(19) United States
(12) Patent Application Publication
(10) Pub. No.: US 2026/0164873 A1
(43) Pub. Date: Jun. 11, 2026

(54) ALIGNMENT MARK IN BUSY PIXEL LAYOUTS

(71) Applicant: VueReal Inc., Waterloo (CA)

(72) Inventors: Gholamreza CHAJI, Kitchener (CA); Ehsanollah FATHI, Waterloo (CA); Hossein Zamani SIBONI, Waterloo (CA)

(73) Assignee: VueReal Inc., Waterloo, ON (CA)

(21) Appl. No.: 18/871,631

(22) PCT Filed: Jun. 7, 2023
(86) PCT No.: PCT/IB2023/055897

§ 371 Date: Dec. 4, 2024

Related U.S. Application Data
(60) Provisional application No. 63/349,872, filed on Jun. 7, 2022.

(51) Int. Cl. H10H 29/02; H10W 46/00

(52) U.S. Cl. CPC H10H 29/02; H10W 46/301

(57) ABSTRACT

This disclosure relates to the process of alignment using at least an alignment mark or structure that exists on the system substrate (or donor substrate) and at least an alignment mark is associated with microdevices. The alignment marks used to align the microdevices are created by changing optical properties of the structure. The disclosure further outlines different alignment mark structures.

### CROSS-REFERENCE TO RELATED APPLICATIONS

This application claims the benefit of, and priority to, U.S. Provisional Patent Application No. 63/349,872 filed on Jun. 7, 2022, which is hereby incorporated by reference herein in its entirety.

### BACKGROUND AND FIELD OF THE INVENTION

The present invention relates to transfer and alignment of microdevices.

### SUMMARY

The present invention relates to an alignment mark structure array of pixels or microdevices identifying a position of a subset of the array of microdevices or pads where the alignment mark structure comprises of, an optical structure in areas not covered by microdevice pads wherein the optical structure changes the optical properties of the area.

The present invention relates to an alignment mark structure, the structure comprising a film formed on areas not covered by pads or microdevices, the film expanded to more than one pixel area and an outer edge of the film forming a shape.

The present invention relates to a method of forming an alignment mark on pixel (or microdevice) array the method comprising, forming a polymer film on top of the array, and patterning the polymer to cover a part of pixel areas and modifying the optical property of the said areas.

The present invention relates to a method to transfer microdevices from a cartridge to a system substrate, the method comprising, identifying for alignment, edges of a first area of the system substrate through image processing wherein an alignment mark is developed by changing optical properties of the first area between microdevices, aligning using the alignment mark the cartridge with the first area of the system substrate, transferring a first selected set of microdevices to the system substrate, and moving the cartridge away from the system substrate.

The present invention relates to a method to align microdevices using an alignment mark structure, the method comprising, forming a film formed on areas not covered by pads or microdevices, expanding the film expanded to more than one pixel area, having an outer edge of the film forming a shape, using an image processing to identify an edge and a shape of the alignment mark and using the information of the shape to align a transfer head or a cartridge with a donor substrate or a system substrate.

### BRIEF DESCRIPTION OF DRAWINGS

The foregoing and other advantages of the disclosure will become apparent upon reading the following detailed description and upon reference to the drawings.

FIG. 1(a) through FIG. 1(f) shows an exemplary method for transferring microdevices into a system substrate.

FIG. 2(a) and FIG. 2(b) show location of microdevices in donor substrate or position of microdevice pads (landing area) on a receiver substrate.

FIG. 3(a) and FIG. 3(b) show an optical structure between the microdevices on the donor substrate or between the pixel areas in the system substrate for alignment marks.

FIG. 3(c) shows a similar pattern or different pattern is used to fill the space between existing traces.

FIG. 3(d) shows the impact of the new filler features/patterns creating a contrast that can be used as alignment mark.

### DETAIL DESCRIPTIONS

The inventions disclosed herein are structures/processes that form alignment marks and methods to transfer microdevices using alignment marks.

Transferring microdevices into a substrate can enable different applications. The microdevices can be light-emitting devices, sensors, chiplet or other applications.

In one case, the microdevices are selectively picked from a donor substrate and then transferred to a system substrate.

In another case, the microdevices can be transferred with offset and print process steps in another case. Here, a selective set of microdevices is transferred from a cartridge substrate to a (system) substrate. The cartridge substrate or system substrate is moved so that the cartridge substrate is covering another area of the system substrate. Here, another set of selected microdevices is transferred into the system substrate.

Independent of transfer method, there is at least in which microdevices, and the system substrate (or pickup head and donor substrate) get aligned. At least an alignment mark exists on the system substrate (or donor substrate) and at least an alignment mark is associated with microdevices. The alignment marks are used to align the microdevice. In all transfer cases, there is still one alignment step with the system substrates with the substrate prior to pick up or transfer.

In some cases, the pixels in system substrate or microdevices in the cartridge are packed with other structures. As a result, adding a large and clear enough alignment mark in the pixels is not practical. Furthermore, the pixel arrays are very repetitive, and the tools may have difficulty using one of the existing pixel structures as an alignment mark.

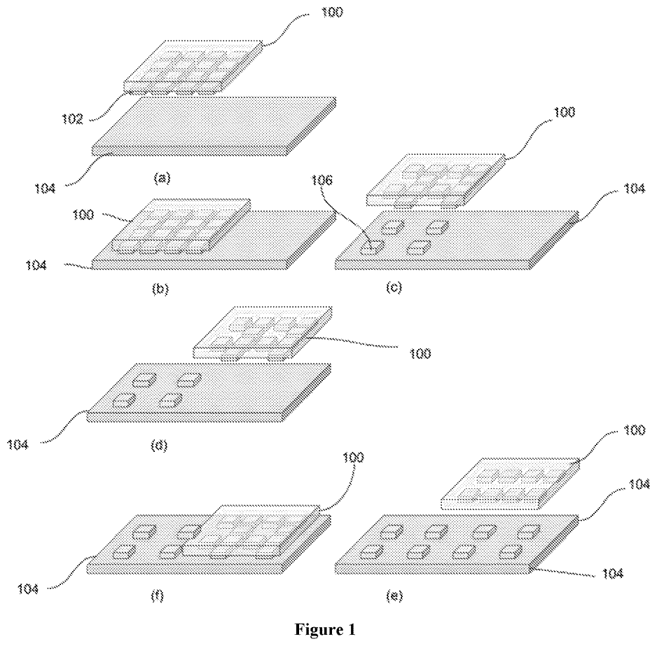

FIG. 1(a) through 1(f) show a transfer case where the microdevices are selectively released from the cartridge. Here the cartridge 100 has several microdevices 102 and it gets aligned with the system substrate 104 (FIG. 1(a)). The cartridge 100 gets in contact or proximity contact with the substrate 104 (FIG. 1(b)) and a selected set of microdevices 106 is transferred into the system substrate 104. The cartridge and the system substrate are moved away and the transferred microdevices 106 stay on the system substrate 104 (FIG. 1(c)). Here, another alignment can be done or the cartridge 100 or system substrate 104 are moved so that the cartridge is covering another part of the system substrate 104. Previous steps repeated in FIG. 1(e) and FIG. 1(f). And the process can continue till the microdevices on the cartridge are finished or the intended areas of the system substrate are populated. In case the transfer is done for areas away from the edge of the pixel array in the system substrate, the alignment mark should exist in the pixel areas.

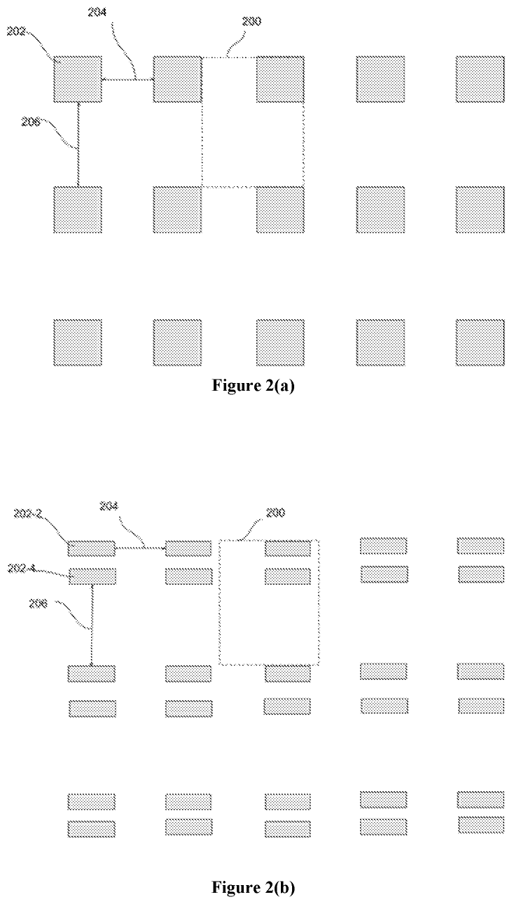

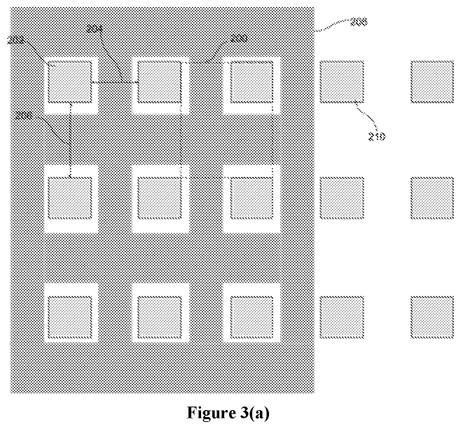

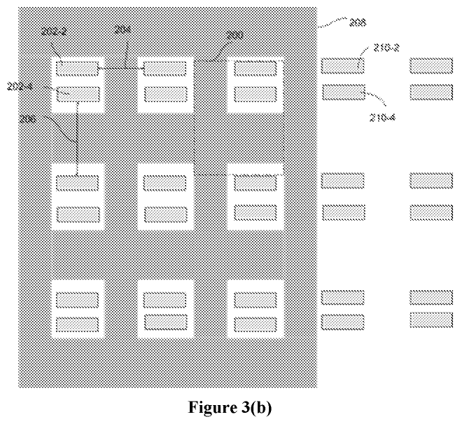

FIG. 2(a) and FIG. 2(b) show an arrangement of contact pads 202, 202-2 and 202-4 for microdevices in a system substrate (or microdevice position 202) in the donor substrate. In FIG. 2(a) the microdevice may have one connection 202 on one side and FIG. 2(b) shows an embodiment where the microdevice has more than one pad 202-2 and 202-4 on one side for connecting the device to the system substrate. The distances 204 and 206 between the pads or microdevices are set by either pixel resolution or the donor resolution. The area 200 shows either pixel area in the system substrate or microdevice pitch area in the donor substrate. As demonstrated in FIG. 2(a) and 2(b), the area 200 between microdevices can be very small. In addition, in the case of system substrate or donor substrate, other structures may exist in the area 200. As a result, the alignment mark may be hard to detect.

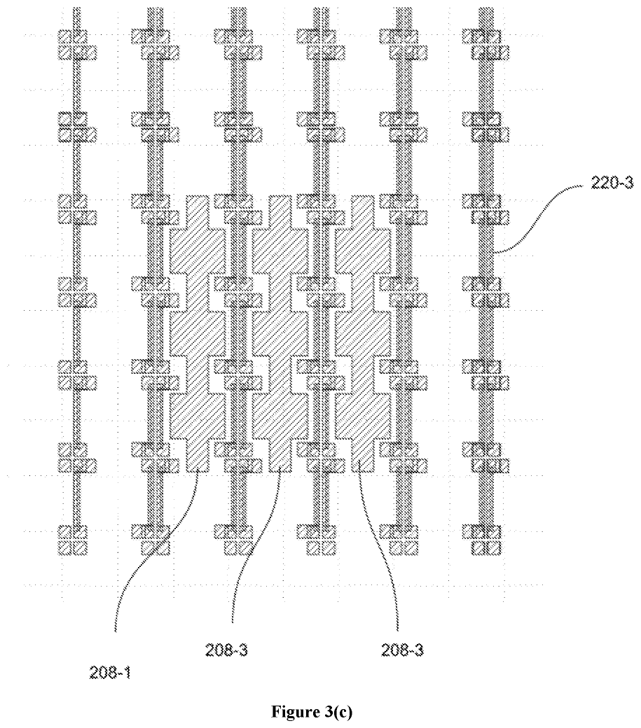

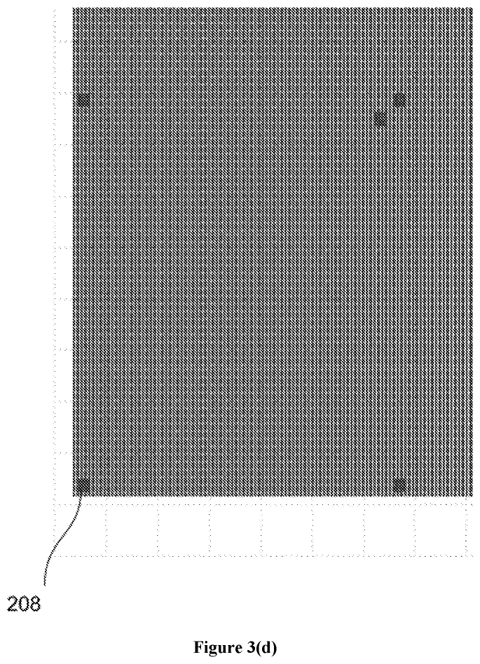

FIG. 3(a) and 3(b) highlight an embodiment where the alignment mark is developed by changing the optical properties of area between microdevices. FIG. 3(a) shows pixel area 200 including a microdevice 202 (or microdevice pad connection 200). In the case of system substrate, the pad 202 will be filled with a microdevice after alignment. In the case of donor substrate, the microdevice 202 will be picked from the substrate after alignment. The distance between 204 and 206 microdevices or pads can be very small. Here, the optical property of the area 208 between one or more than one microdevice (or pad) 202 changes. The structure forming the optical change can be a continuation or combination of several parts. For alignment, the edges of the structures 208 are identified through image processing, and the structure and its relative position can be used to align the microdevices with system substrate (or pick up head with donor substrate). As can be seen some microdevices 210 (or pads) are outside the structure 208.

FIG. 3(b) shows a similar structure as demonstrated in FIG. 3(a). Here, the microdevice or the pixel in the system substrate has more than one pad (202-2, 202-4, 210-2 and 210-4). One can use the area between the two pads as part of the optical structure 208 as well. The rest of the structure is the same as the one described in FIG. 3(a).

FIG. 3(c) shows another related embodiment, where a similar pattern or different pattern of optical structures 208-1, 208-2 and 208-3 is used to fill the space between existing traces 220-3. The extra features can be used together as an alignment mark. The pattern can fill the space between traces. This features can be metal, polymer, or other forms of layers.

In another related embodiment, the impact of the new filler features/patterns shown in FIG. 3(c) 208-1, 208-2, and 208-3 creating a contrast that can be used as alignment mark 208 as demonstrated in FIG. 3(d). This contrast can be enhanced by image processing or image capture techniques (e.g., zoom out, etc.).

In one related embodiment, the structure/area 208 is developed by a layer deposited and patterned on top layer before or after forming the pads. Here, a dielectric layer may be used if the layer used for structure is conductive prior to the formation of the structure layer 208. In another case, the pads 202, 202-2, 202-4, 210, 210-2, and 210-4 are formed after the structure. If the pads are crossing the structure, a dielectric may be used between the pads and the structure layers if the layer is conductive. The deposition can be done through evaporation, spray coating, inkjet coating, PECVD, PVD, ALD, e-beam, or other deposition methods. Here, the structure can be conductive, metallic, polymer, dielectric, or combination of these layers.

In another related embodiment, the structure can be formed by modifying the surface of one of the existing layers in the pixel area. The modification can be done through wet or dry etching process. The modification can be either as surface roughness or thinning a layer to create an optical contrast.

In another related embodiment, the structure can be removed after the microdevices are transferred into the system substrate. Here, a dry or wet etching process can be used to remove the structure.

In another related embodiment, if one of the structure layers cannot be removed, the other areas in the system substrate can be covered with the layer to provide similar/comparable optical properties.

In another related embodiment, the layer property in areas other than the structure area can be modified after microdevice transfer is completed to have similar optical properties across the system substrate.

In another related embodiment, a part of the surface of the system substrate including the areas associated with optical structure can be covered by layer(s) to reduce or remove the effect of structure and therefore creating similar optical properties for all relevant areas in the system substrate. The layer can be dielectric, organic, metallic, or other types of layers. The layer can be opaque or reflective.

In one related embodiment, a structure that extends between patterns in one pixel or between at least two adjacent pixel areas is formed to create an alignment mark. The structure can change the optical property of the parts it covers. The structure can be a continuous or a possible combination of separated smaller structures.

In another related embodiment, the structure can be formed by a dielectric, metal or polymer or combination of different layers.

In another related embodiment, the shape of some microdevices is different from the other microdevices. These microdevices form an alignment mark. In one related embodiment each microdevice with different shape is an alignment mark, in another related embodiment a combination of more than one microdevices form an alignment mark.

While the present disclosure is susceptible to various modifications and alternative forms, specific embodiments or implementations have been shown by way of example in the drawings and will be described in detail herein. However, it should be understood that the disclosure is not intended to be limited to the particular forms disclosed. Rather, the disclosure is to cover all modifications, equivalents, and alternatives falling within the spirit and scope of the invention as defined by the appended claims.

1-14. (canceled)

15. A method to transfer microdevices from a cartridge to a system substrate, the method comprising:
identifying for alignment, edges of a first area of the system substrate through image processing wherein an alignment mark is developed by changing optical properties of the first area between microdevices;
aligning using the alignment mark the cartridge with the first area of the system substrate;
transferring a first selected set of microdevices to the system substrate; and
moving the cartridge away from the system substrate.

16. The method of claim 15 further comprising:
re-aligning the cartridge with a second area of the system substrate wherein another alignment mark is developed by changing optical properties of the second area between microdevices;
transferring a second selected set of microdevices to the system substrate;
moving the cartridge away from the system substrate; and
re-aligning with the remaining intended areas of the system substrate by repeating previous steps to populate the remaining intended areas of the system substrate or when the microdevices in the cartridge are finished.

17. The method of claim 15, wherein the transfer is done for areas away from an edge of a pixel array in the system substrate, wherein an alignment mark exists in a pixel area.

18. The method of claim 15, wherein the microdevice has one connection on one side.

19. The method of claim 15, wherein the microdevice has more than one pad on one side for connecting the microdevice to the system substrate.

20. The method of claim 19, wherein distances between the pads or microdevices are set by either a pixel resolution or a donor resolution.

21. The method of claim 15, wherein areas forming the optical change are a continuation or combination of several parts.

22. The method of claim 19, wherein the pads are part of the areas with the optical changes.

23. The method of claim 21, wherein an optical change area or a structure is developed by a layer deposited and patterned on a top layer before or after forming the pads.

24. The method of claim 22, where a dielectric layer is used if the layer used for the structure is conductive prior to a formation of the optical change area.

25. The method of claim 22, wherein the pads are formed after the structure.

26. The method of claim 18, wherein the pads are formed after the structure.

27. The method of claim 25, wherein if the pads are crossing the structure, a dielectric is used between the pads and structure layers if the layers are conductive.

28. The method of claim 27, wherein a dielectric deposition is done through evaporation, spray coating, inkjet coating, PECVD, PVD, ALD or e-beam and wherein the optical change area is conductive, metallic, a polymer, a dielectric or a combination of these layers.

29. The method of claim 23, wherein the structure is formed by modifying a surface of one of the existing layers in the pixel area using a wet or a dry etching process.

30. The method of claim 29, wherein the modification is either a surface roughness or thinning a layer to create an optical contrast.

31. The method of claim 23, wherein the structure is removed after the microdevices are transferred into the system substrate using a dry or wet etching process.

32. The method of claim 23, wherein if one of a structure layers is not removable, other areas in the system substrate are covered with the layer to provide similar/comparable optical properties.

33. The method of claim 23, wherein a layer property in areas other than the structure area is modified after microdevice transfer is completed to have similar optical properties across the system substrate.

34. The method of claim 23, wherein a part of the surface of the system substrate including the areas associated with optical structure are covered by layers to reduce or remove the effect of structure creating similar optical properties for all relevant areas in the system substrate wherein the layer is one of dielectric, organic, or metallic wherein further the layer is opaque or reflective.

35. The method of claim 23, wherein a structure that extends between patterns in one pixel or between at least two adjacent pixel areas is formed to create an alignment mark.

36. The method of claim 35, wherein the structure changes the optical property of the parts it covers and is either a continuous or a possible combination of separated smaller structures.

37. The method of claim 23, wherein the shape of some microdevices is different from the other microdevices and these microdevices form an alignment mark.

38. The method of claim 37, wherein each microdevice with a different shape is an alignment mark.

39. The method of claim 37, wherein a combination of more than one microdevices forms an alignment mark.

40. A method to align microdevices using an alignment mark structure, the method comprising:
forming a film formed on areas not covered by pads or microdevices;
expanding the film expanded to more than one pixel area;
having an outer edge of the film forming a shape;
using an image processing to identify an edge and a shape of the alignment mark; and
using the information of the shape to align a transfer head or a cartridge with a donor substrate or a system substrate.

41. The method of claim 40, wherein an inner edge forms a different shape, and the image processing detects an inner shape for enhancing an alignment accuracy.

42. The method of claim 40, wherein the film comprises a single layer or a multi-layer.

43. The method of claim 40, wherein the film is either a polymer, a dielectric, or metallic.

44. The method of claim 40, wherein in case of the film being conductive, a dielectric is deposited before or after the said film to isolate it from a main pixel structure.

45. The method of claim 40, wherein a similar pattern or different pattern of optical structures is used to fill a space between existing traces creating an alignment mark.

46. The method of claim 40, wherein new filler patterns create a contrast to be used as an alignment mark.
